(19) United States
(12) Patent Application Publication
(10) Pub. No.: US 2022/0207077 A1
(43) Pub. Date: Jun. 30, 2022

(54) IMAGE SEARCH DEVICE, COMPONENT MOUNTING SYSTEM, AND IMAGE SEARCH METHOD

(71) Applicant: YAMAHA HATSUDOKI KABUSHIKI KAISHA, Iwata-shi, Shizuoka-ken (JP)

(72) Inventors: Yuichi MATSUSHITA, Iwata-shi (JP); Akinobu UESUGI, Iwata-shi (JP)

(73) Assignee: YAMAHA HATSUDOKI KABUSHIKI KAISHA, Iwata-shi, Shizuoka-ken (JP)

(21) Appl. No.: 17/603,322

(22) PCT Filed: Apr. 17, 2019
(86) PCT No.: PCT/JP2019/016548

§ 371 Date: Oct. 12, 2021

(51) Int. Cl. G06F 16/535; G06F 16/538

(52) U.S. Cl. CPC G06F 16/535; G06F 16/538

(57) ABSTRACT

An image search device includes an image storage configured to store a plurality of images captured in a mounting process to mount a component on a board, and a controller configured to retrieve an image according to a search condition from the plurality of images stored in the image storage. The controller is configured to perform a control to retrieve an image from the plurality of images in the image storage according to a first search condition set by a user, and display, together with a selected image selected by the user from the retrieved image, a related image retrieved according to a second search condition different from the first search condition based on information on the selected image.

### CROSS-REFERENCE TO RELATED APPLICATION

This application is a National Stage of International Patent Application No. PCT/JP2019/016548, filed Apr. 17, 2019, the entire content of which is incorporated herein by reference.

### BACKGROUND

### Technical Field

The present disclosure relates to an image search device, a component mounting system, and an image search method, and more particularly, it relates to an image search device, a component mounting system, and an image search method to display images captured in a mounting process to mount components on a board.

### Background Art

Conventionally, a configuration that displays images captured in a mounting process to mount components on a board is known. Such a configuration is disclosed in Japanese Patent No. 6154120, for example.

Japanese Patent No. 6154120 discloses a management system including an image storage configured to store images captured during the mounting operation to mount electronic components on a board, and a controller configured or programmed to manage the history of the electronic component mounting operation in association with the captured images. In the management system disclosed in Japanese Patent No. 6154120, the controller is configured or programmed to perform a control to associate images of a plurality of electronic components mounted on the same board and display the associated images of the plurality of electronic components mounted on the same board on a display.

### SUMMARY

However, in the management system disclosed in Japanese Patent No. 6154120, the associated images of the plurality of electronic components mounted on the same board are displayed on the display. Therefore, images displayed when the images captured during the mounting operation are confirmed are the images of the plurality of electronic components mounted on the same board, which have been associated in advance, and thus the images captured during the mounting operation that have not been associated in advance cannot be displayed at the same time. Consequently, a user needs to perform a separate search in order to confirm the images captured during the mounting operation that have not been associated, and thus it is difficult to easily confirm a plurality of related images captured during the mounting operation that have not been associated in advance.

Accordingly, the present disclosure provides an image search device, a component mounting system, and an image search method each enabling a plurality of related images captured during the mounting operation that have not been associated in advance to be easily confirmed.

An image search device according to a first aspect of the present disclosure includes an image storage configured to store a plurality of images captured in a mounting process to mount a component on a board, and a controller configured to retrieve an image according to a search condition from the plurality of images stored in the image storage. The controller is configured to perform a control to retrieve an image from the plurality of images in the image storage according to a first search condition set by a user, and display, together with a selected image selected by the user from the retrieved image, a related image retrieved according to a second search condition different from the first search condition based on information on the selected image.

The component mounting system according to the first aspect of the present disclosure is configured as described above such that the controller retrieves the related image according to the second search condition different from the first search condition used to retrieve the selected image based on the information on the selected image, and thus the related image can be extracted without associating a plurality of images in advance. Consequently, it is not necessary for the user to perform a separate retrieval, and thus it is possible to easily confirm a plurality of related images captured during the mounting operation that have not been associated in advance. Furthermore, the selected image and the related image are displayed on the same screen, and thus it is possible to easily understand the mounting state and identify the cause of a defect.

In the aforementioned image search device according to the first aspect, the first search condition is preferably a condition set based on information including at least one of component information, board information, information on a component mounting position, information on a working device that works on the board, information on a working unit that works on the board, information on a component supply unit that supplies the component, or information on a work date and time. Accordingly, an image can be retrieved according to the first search condition set by the user based on the component information, the board information, the information on a component mounting position, the information on a working device that works on the board, the information on a working unit that works on the board, the information on a component supply unit that supplies the component, or the information on a work date and time.

In the aforementioned image search device according to the first aspect, the controller is preferably configured to perform a control to display a plurality of the related images together with the selected image. Accordingly, the plurality of related images can be confirmed together with the selected image, and thus it is possible to more easily understand the mounting state and identify the cause of the defect.

In this case, the controller is preferably configured to store information on the related image selected from the plurality of related images with respect to the selected image in a storage, and reflect the information on the related image stored in the storage to set the second search condition. Accordingly, the second search condition can be set such that the related image frequently selected among the plurality of related images is easily retrieved, for example, and thus a more suitable related image can be extracted.

In the aforementioned image search device according to the first aspect, the controller is preferably configured to retrieve the related image according to the second search condition according to a type of mounting defect when the selected image selected by the user is an image related to a mounting defect of the component. Accordingly, the related image for identifying the cause can be displayed according to the type of mounting defect, and thus the user can efficiently confirm the image. Thus, the user can efficiently perform an operation to identify the mounting defect. Furthermore, it is possible to prevent extraction of an image having low relevance according to the type of mounting defect, and thus the retrieval operation can be performed efficiently while the retrieval time can be shortened.

In the aforementioned image search device according to the first aspect, the controller is preferably configured to perform a control to store OK/NG of an inspection result of component mounting in a storage, and display an image of a same type of another component with an NG inspection result as the related image together with the selected image when the selected image is an image with an NG inspection result. Accordingly, it is not necessary for the user to retrieve and display another similar image with an NG inspection result, and thus the work burden can be reduced. Furthermore, similar images with an NG inspection result can be displayed in a list, and thus it is possible to more easily understand the mounting state and identify the cause of the defect.

In the aforementioned image search device according to the first aspect, the controller is preferably configured to perform a control to display the second search condition together with the related image. Accordingly, the user can visually confirm the search condition of the related image displayed together with the selected image.

In the aforementioned image search device according to the first aspect, the controller is preferably configured to, when a plurality of the second search conditions are settable for the selected image, retrieve the related image according to one second search condition selected based on a user's selection or a predetermined condition among the plurality of settable second search conditions. Accordingly, the related image can be retrieved according to one second search condition selected from the plurality of second search conditions, and thus the related image can be retrieved according to a more suitable search condition.

In this case, the controller is preferably configured to perform a control to display the plurality of second search conditions in a selectable manner together with the selected image. Accordingly, the user can easily select a desired search condition from the plurality of second search conditions.

A component mounting system according to a second aspect of the present disclosure includes a component mounting device configured to mount a component on a board, and an image search device. The image search device includes an image storage configured to store a plurality of images captured in a mounting process to mount the component on the board, and a controller configured to retrieve an image according to a search condition from the plurality of images stored in the image storage. The controller is configured to perform a control to retrieve an image from the plurality of images in the image storage according to a first search condition set by a user, and display, together with a selected image selected by the user from the retrieved image, a related image retrieved according to a second search condition different from the first search condition based on information on the selected image.

The component mounting system according to the second aspect of the present disclosure is configured as described above such that the controller retrieves the related image according to the second search condition different from the first search condition used to retrieve the selected image based on the information on the selected image, and thus the related image can be extracted without associating a plurality of images in advance. Consequently, it is not necessary for the user to perform a separate retrieval, and thus it is possible to provide the component mounting system enabling a plurality of related images captured during the mounting operation that have not been associated in advance to be easily confirmed. Furthermore, the selected image and the related image are displayed on the same screen, and thus it is possible to easily understand the mounting state and identify the cause of a defect.

An image search method according to a third aspect of the present disclosure includes storing a plurality of images captured in a mounting process to mount a component on a board, and retrieving an image from the plurality of stored images according to a first search condition and displaying, together with a selected image selected from the retrieved image, a related image retrieved according to a second search condition different from the first search condition based on information on the selected image.

The image search method according to the third aspect of the present disclosure is configured as described above such that the related image is retrieved according to the second search condition different from the first search condition used to retrieve the selected image based on the information on the selected image, and thus the related image can be extracted without associating a plurality of images in advance. Consequently, it is not necessary for a user to perform a separate retrieval, and thus it is possible to provide the image search method enabling a plurality of related images captured during the mounting operation that have not been associated in advance to be easily confirmed. Furthermore, the selected image and the related image are displayed on the same screen, and thus it is possible to easily understand the mounting state and identify the cause of a defect.

In the aforementioned image search method according to the third aspect, the first search condition is preferably a condition set based on information including at least one of component information, board information, information on a component mounting position, information on a working device that works on the board, information on a working unit that works on the board, information on a component supply unit that supplies the component, or information on a work date and time. Accordingly, an image can be retrieved according to the first search condition set by the user based on the component information, the board information, the information on a component mounting position, the information on a working device that works on the board, the information on a working unit that works on the board, the information on a component supply unit that supplies the component, or the information on a work date and time.

In the aforementioned image search method according to the third aspect, a plurality of the related images are preferably displayed together with the selected image. Accordingly, the plurality of related images can be confirmed together with the selected image, and thus it is possible to more easily understand the mounting state and identify the cause of the defect.

In the aforementioned image search method according to the third aspect, the related image is preferably retrieved according to the second search condition according to a type of mounting defect when the selected image is an image related to a mounting defect of the component. Accordingly, the related image for identifying the cause can be displayed according to the type of mounting defect, and thus the user can efficiently confirm the image. Thus, the user can efficiently perform an operation to identify the mounting defect. Furthermore, it is possible to prevent extraction of an image having low relevance according to the type of mounting defect, and thus the retrieval operation can be performed efficiently while the retrieval time can be shortened.

In the aforementioned image search method according to the third aspect, OK/NG of an inspection result of component mounting is preferably stored, and an image of a same type of another component with an NG inspection result is preferably displayed as the related image together with the selected image when the selected image is an image with an NG inspection result. Accordingly, it is not necessary for the user to retrieve and display another similar image with an NG inspection result, and thus the work burden can be reduced. Furthermore, similar images with an NG inspection result can be displayed in a list, and thus it is possible to more easily understand the mounting state and identify the cause of the defect.

In the aforementioned image search method according to the third aspect, the second search condition is preferably displayed together with the related image. Accordingly, the user can visually confirm the search condition of the related image displayed together with the selected image.

According to the present disclosure, as described above, it is possible to easily confirm the plurality of related images captured during the mounting operation that have not been associated in advance.

### BRIEF DESCRIPTION OF THE DRAWINGS

FIG. 1 is a block diagram showing a component mounting system according to an embodiment of the present disclosure;

FIG. 2 is a diagram showing the overall structure of a component mounting device of the component mounting system according to the embodiment of the present disclosure;

FIG. 3 is a diagram showing a first screen example of an image search device of the component mounting system according to the embodiment of the present disclosure;

FIG. 4 is a diagram showing a second screen example of the image search device of the component mounting system according to the embodiment of the present disclosure; and

FIG. 5 is a diagram showing an example of pull-down display of a second search condition of the component mounting system according to the embodiment of the present disclosure.

### DETAILED DESCRIPTION

An embodiment embodying the present disclosure is hereinafter described on the basis of the drawings.

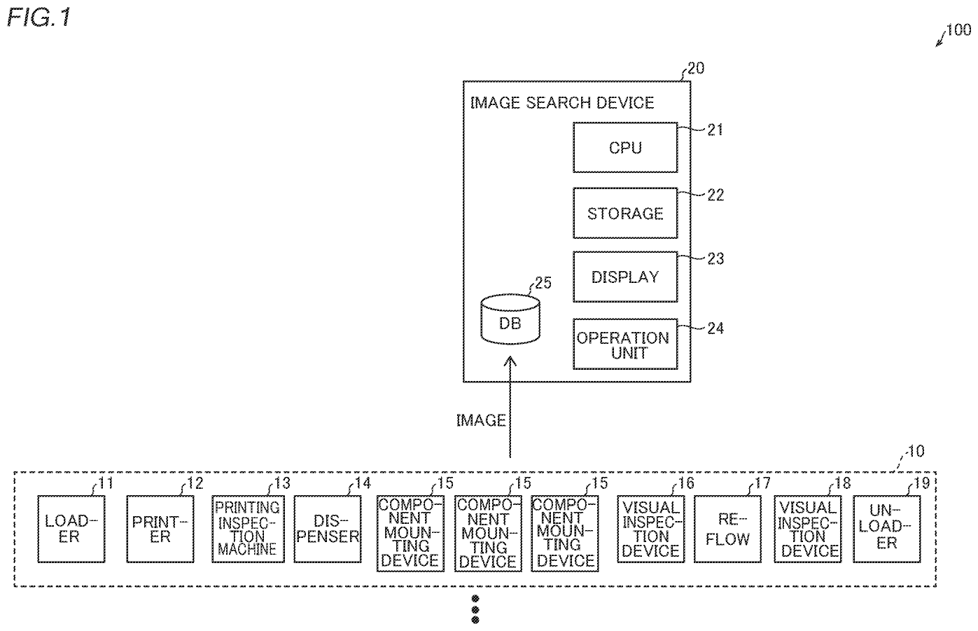

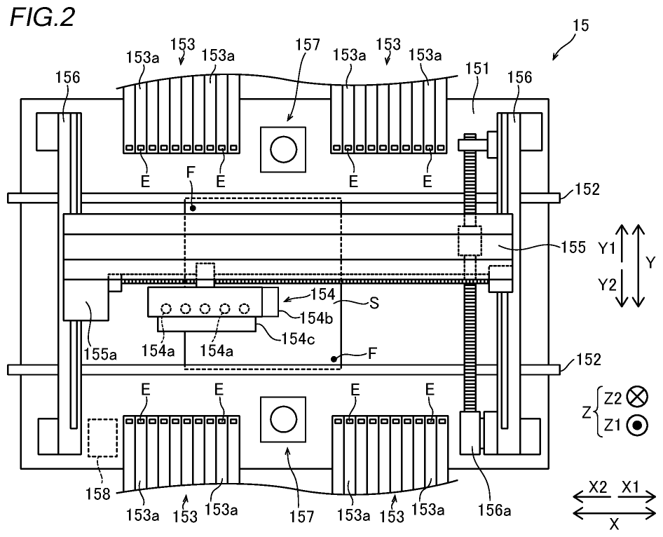

The structure of a component mounting system 100 according to the embodiment of the present disclosure is now described with reference to FIGS. 1 and 2.

Structure of Component Mounting System

The component mounting system 100 according to this embodiment of the present disclosure is configured to mount components E on a board S to manufacture the board S on which the components E have been mounted. As shown in FIG. 1, the component mounting system 100 includes a component mounting line 10 and an image search device 20.

A plurality of component mounting lines 10 are provided. The component mounting lines 10 each includes a loader 11, a printer 12, a printing inspection machine 13, a dispenser device 14, a plurality of component mounting devices 15, a visual inspection device 16, a reflow device 17, and a visual inspection device 18, and unloader 19. In the component mounting line 10, the board S is conveyed from the upstream side (left side) to the downstream side (right side) along the production line.

Structure of Component Mounting Line

The structure of each device of the component mounting line 10 is now described.

The loader 11 has a role of holding the board (wiring board) S before the components E are mounted and carrying the board S into the component mounting line 10. The components E include small pieces of electronic components such as LSIs, ICs, transistors, capacitors, and resistors.

The printer 12 is a screen printer and has a function of applying cream solder on a mounting surface of the board S. Furthermore, the printer 12 includes an imager to image fiducial marks F of the board S. The printer 12 transmits, to the image search device 20, an image captured by the imager together with information on a target to be imaged.

The printing inspection machine 13 has a function of inspecting the state of the cream solder printed by the printer 12. Specifically, the printing inspection machine 13 images the board S by an imager and inspects the state of the printed cream solder based on the captured image. Furthermore, the print inspection machine 13 transmits, to the image search device 20, the image captured by the imager together with the information on the target to be imaged.

The dispenser device 14 has a function of applying cream solder, an adhesive, etc. to the board S.

The component mounting devices 15 have a function of mounting components at predetermined mounting positions on the board S on which cream solder has been printed. A plurality of (three) component mounting devices 15 are arranged along the conveyance direction of the board S. The plurality of component mounting devices 15 have a similar structure. As shown in FIG. 2, the component mounting devices 15 each include a base 151, a pair of conveyors 152, component supply units 153, a head unit 154, a support 155, a pair of rails 156, and component recognition imagers 157, and a controller 158.

The pair of conveyors 152 are installed on the base 151 and convey the board S in an X direction. Furthermore, the pair of conveyors 152 hold the board S being conveyed in a stopped state at a mounting operation position. A distance between the pair of conveyors 152 in a Y direction can be adjusted according to the dimensions of the board S.

The component supply units 153 are arranged outside (Y1 and Y2 sides) of the pair of conveyors 152. Furthermore, a plurality of tape feeders 153a are arranged in the component supply units 153.

The tape feeders 153a hold reels on which tapes that hold a plurality of components E at a predetermined interval are wound. The tape feeders 153a are configured to supply the components E from the tip ends of the tape feeders 153a by rotating the reels to feed the tapes that hold the components E.

The head unit 154 is provided so as to move between an area above the pair of conveyors 152 and areas above the component supply units 153. Furthermore, the head unit 154 includes a plurality of (five) mounting heads 154a having nozzles attached to the lower ends, a board recognition imager 154b, and a camera unit 154c.

The mounting heads 154a are configured to mount the components E on the board S. Specifically, the mounting heads 154a are configured to be movable up and down (movable in a Z direction), and are configured to suction and hold the components E supplied from the tape feeders 153a by a negative pressure generated at the tip ends of the nozzles by an air pressure generator and to mount the components E at the mounting positions on the board S.

The board recognition imager 154b is configured to image the fiducial marks F of the board S in order to recognize the position and orientation of the board S. The positions of the fiducial marks F are imaged and recognized such that the mounting positions of the components E on the board S can be accurately acquired. The board recognition imager 154b is configured to image the board S from above (Z1 direction side). The image captured by the board recognition imager 154b is transmitted together with the information on the target to be imaged to the image search device 20.

The camera unit 154c is configured to image the components suctioned to the nozzles of the mounting heads 154a from the side. Furthermore, the camera unit 154c is configured to image the nozzles from the side before and after suction of the components E. The image captured by the camera unit 154c is transmitted together with the information on the target to be imaged to the image search device 20.

The support 155 includes an X-axis motor 155a. The support 155 is configured to move the head unit 154 in the X direction along the support 155 by driving the X-axis motor 155a. Opposite ends of the support 5 are supported by the pair of rails 156.

The pair of rails 156 are fixed on the base 151. A rail 156 on the X1 side includes a Y-axis motor 156a. The rails 156 are configured to move the support 155 in the Y direction orthogonal to the X direction along the pair of rails 156 by driving the Y-axis motor 156a. The head unit 154 is movable in the X direction along the support 155, and the support 155 is movable in the Y direction along the rails 156 such that the head unit 154 is movable in the X and Y directions.

The component recognition imagers 157 are fixed on the upper surface of the base 151. The component recognition imagers 157 are arranged outside (Y1 and Y2 sides) of the pair of conveyors 152. The component recognition imagers 157 are configured to image the components E suctioned by the nozzles of the mounting heads 154a from below (Z2 direction side) in order to recognize the suction states (suction orientations) of the components E prior to mounting of the components E. Thus, the suction states of the components E suctioned by the nozzles of the mounting heads 154a can be acquired. The images captured by the component recognition imagers 157 are transmitted together with the information on the target to be imaged to the image search device 20.

The controller 158 includes a CPU, and is configured to control the overall operation of the component mounting device 15 such as the board S conveying operation performed by the pair of conveyors 152, the mounting operation performed by the head unit 154, and the imaging operations performed by the component recognition imagers 157 and the board recognition imager 154b. Furthermore, the controller 158 is configured to perform a control to transmit the captured images to the image search device 20. The controller 158 transmits, to the image search device 20, the images of the components E, the image of the surface of the board S, the image of the fiducial marks of the board S, the images of the nozzles of the mounting heads 154a, and the images of the component supply positions of the tape feeders 153a.

As shown in FIG. 1, the visual inspection device 16 is provided downstream of the plurality of component mounting devices 15. The visual inspection device 16 has a function of inspecting the appearance of the board S on which the components E have been mounted by the component mounting devices 15. Specifically, the visual inspection device 16 images the board S by an imager, and inspects the mounted states of the components E on the board S based on the captured image. Furthermore, the visual inspection device 16 transmits, to the image search device 20, the image captured by the imager together with the information on the target to be imaged.

The reflow device 17 has a function of melting the solder by performing a heat treatment and joining the components E to electrode portions of the board S. The reflow device 17 is configured to perform the heat treatment while conveying the board S on the lane.

The visual inspection device 18 is provided downstream of the reflow device 17. The visual inspection device 18 has a function of inspecting the appearance of the board S heat-treated by the reflow device 17. Specifically, the visual inspection device 18 images the board S by an imager, and inspects the mounted states of the components E on the board S based on the captured image. Furthermore, the visual inspection device 18 transmits, to the image search device 20, the image captured by the imager together with the information on the target to be imaged.

The unloader 19 has a role of discharging the board S on which the components E have been mounted from the component mounting line 10.

Structure of Image Search Device

The structure of the image search device 20 is now described.

The image search device 20 includes a personal computer. Furthermore, the image search device 20 is used to retrieve a target image among a plurality of images captured in a mounting process to mount the components E on the board S. The image search device 20 manages the component mounting line 10.

The image search device 20 includes a central processing unit (CPU) 21, a storage 22, a display 23, an operation unit 24, and a database (DB) 25. The CPU 21 controls each portion of the image search device 20. Furthermore, the CPU 21 executes predetermined programs to perform an image search process and a component mounting line management process. The storage 22 is configured to store information. The display 23 displays a screen for operating the image search device 20. Furthermore, the display 23 displays an image that is an image search result of the image search device 20. The operation unit 24 receives an operation from a user. The operation unit 24 includes an input device such as a keyboard or a mouse. The DB 25 stores a plurality of images captured in the mounting process to mount the components E on the board S. That is, the DB 25 stores the images transmitted from each device (the printer 12, the printing inspection machine 13, the component mounting devices 15, the visual inspection device 16, and the visual inspection device 18) of the component mounting line 10. The CPU 21 is an example of a “controller” in the claims. The DB 25 is an example of an “image storage” in the claims.

In this embodiment, the CPU 21 is configured to retrieve images from the plurality of images stored in the DB 25 according to a search condition. The images stored in the DB 25 are associated with information such as a board name, a silk name, a board ID, a component number, a feeder number, a time, a head number, and a nozzle number. The CPU 21 is configured to retrieve images according to the search condition and display a list of information of the corresponding images on the display 23. For example, the CPU 21 displays a list of information such as the imaging positions, targets to be imaged, and imaging times of a plurality of images extracted by the search on the display 23.

For example, a print inspection image is retrieved by the board name and/or the silk name Furthermore, an inspection image after mounting is retrieved by the board name and/or the silk name. A feeder image is retrieved by the component number and/or the feeder number. A mark image is retrieved by the time and/or the board ID. A nozzle image is retrieved by the head number and/or the nozzle number. Component recognition images from below and from the side are retrieved by the board name and/or the silk name.

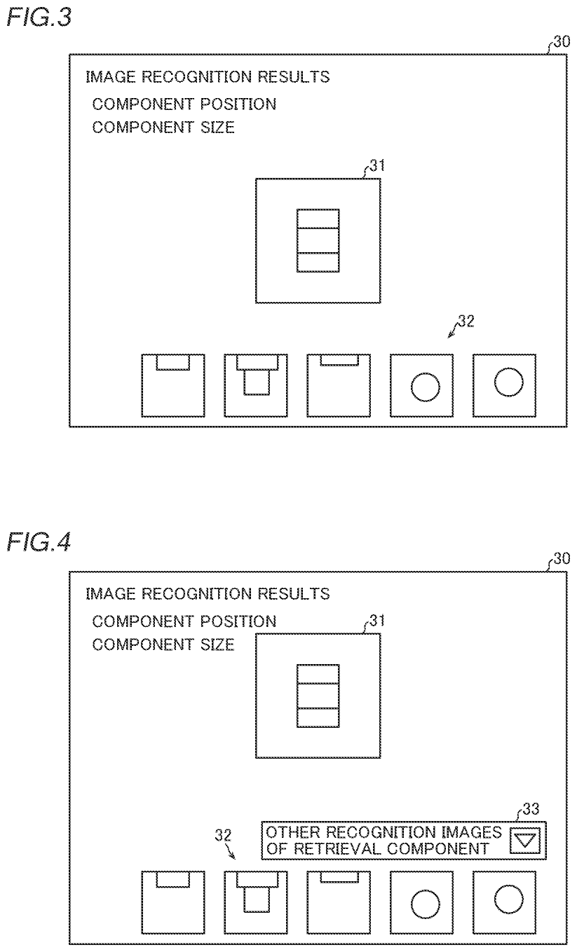

Specifically, the CPU 21 retrieves images from the plurality of images in the DB 25 according to a first search condition set by the user. Furthermore, the CPU 21 displays a list of information on the retrieved and extracted images on the display 23. When the user selects one image based on the displayed list of information on the images, the CPU 21 displays a selected image 31 on a screen 30, as shown in FIG. 3. Furthermore, the CPU 21 performs a control to retrieve images from the plurality of images in the DB 25 according to the first search condition set by the user, and display related images 32 retrieved according to a second search condition different from the first search condition based on the information on the selected image 31 together with the selected image 31 selected by the user from the retrieved images. That is, the CPU 21 retrieves images according to the second search condition including the information on the selected image 31, which is different from the first search condition, and extracts the related images 32 from the DB 25. Then, the CPU 21 displays the related images 32 together with the selected image 31 on the screen 30.

When the selected image 31 is an image of the component E at a mounting point, the related images 32 are a component recognition image from the side, recognition images of the fiducial marks F of the board S, an inspection image of a target component suction nozzle, an image of a target component supply feeder, a print inspection image, an inspection image after mounting, etc., for example. Furthermore, information for retrieving the related images 32 includes information such as a board, a mounting point, a working machine, a working tool, a component replenishment tool, a date and time, etc.

The first search condition is a condition set based on information including at least one of component information, board information, information on a component mounting position, information on a working device that works on a board, information on a working unit that works on a board, information on a component supply unit that supplies components, or information on a work date and time. The component information includes information such as the type, shape, and size of a component to be mounted. The board information includes information such as a board type and a board ID. The information on a component mounting position includes information on component mounting coordinates (X, Y) on a board. The information on a working device that works on a board includes information on the type and state of each device (the printer 12, the printing inspection machine 13, the component mounting devices 15, the visual inspection device 16, and the visual inspection device 18). The information on a working unit that works on a board includes information on the mounting heads 154a and the nozzles of the component mounting device 15. The information on a component supply unit includes information such as the type and ID of the tape feeders 153a.

For example, when a mounting defect of the component E on the board S occurs, the user retrieves images according to the first search condition and confirms the images to analyze the cause of the mounting defect. When the mounting heads 154a poorly suction the components E or the mounting operation is slow due to the mounting heads 154a, for example, the user retrieves images according to the first search condition and confirms the images to analyze the cause of the problem.

As shown in FIG. 3, the CPU 21 performs a control to display the plurality of related images 32 together with the selected image 31. When there is one related image 32 with respect to the selected image 31, the CPU 21 displays one related image 32 together with the selected image 31 on the screen 30. When there is no related image 32 with respect to the selected image 31, the CPU 21 displays the selected image 31 on the screen 30 without displaying the related image 32. Furthermore, the CPU 21 displays the image recognition results of the selected image together with the selected image 31. The image recognition results include information such as a component position, a component size, a board name, a silk name, a board ID, a component number, a feeder number, a time, a head number, and a nozzle number.

The CPU 21 displays the related images 32 in a size smaller than that of the selected image 31. Furthermore, the CPU 21 displays the plurality of related images 32 side by side. The plurality of related images 32 are displayed side by side in a right-left direction, for example. Furthermore, the plurality of related images 32 are displayed below the selected image 31.

The CPU 21 stores information on a related image 32 selected from the plurality of related images 32 with respect to the selected image 31 in the storage 22, and reflects the information on the related image 32 stored in the storage 22 to set the second search condition. For example, learning is performed to add points to a search condition having a large number of times of display, and the search condition having a large number of points is preferentially set as the second search condition. That is, the search condition of the related image 32 frequently selected by the user to confirm the details among the plurality of related images 32 is preferentially set as the second search condition.

The CPU 21 displays the plurality of related images 32 side by side in order of priority. For example, the CPU 21 displays the related images 32 having a large number of times of display and a large number of points side by side in order from the left. Furthermore, for example, the CPU 21 displays side by side the plurality of related images 32 in order of the Japanese syllabary, in alphabetical order, or in numerical order based on image names of the plurality of related images 32.

The CPU 21 switches and sequentially displays the plurality of related images 32 to be displayed at regular time intervals (five seconds, for example). The CPU 21 sequentially displays the plurality of related images 32, displays a predetermined number of related images 32, and then displays the first related image 32. Then, the CPU 21 repeats a control to sequentially display the plurality of related images 32.

When one related image 32 is selected from the plurality of displayed related images 32, the CPU 21 displays the selected related image 32 as the selected image 31 in a large size. In this case, the related images 32 may be retrieved according to a new second search condition based on information on the selected related image 32 (new selected image 31). In this case, the CPU 21 displays the retrieved related images 32 together with the selected related image 32 (new selected image 31).

The CPU 21 retrieves the related images 32 according to the second search condition according to the type of mounting defect when the selected image 31 selected by the user is an image related to the mounting defect of the component E. The type of mounting defect is determined by information from each device (the printer 12, the printing inspection machine 13, the component mounting devices 15, the visual inspection device 16, and the visual inspection device 18) or a user's selection, for example.

For example, in the case of a mounting defect in which the mounting position of the component E on the board S is displaced, conditions for retrieving a component recognition image of the corresponding component E from below, a mark recognition image of the corresponding board S (fiducial marks of the entire board or a local fiducial mark of the board), and/or a posture image of the corresponding component E from the side immediately before mounting are set as the second search condition. In the case of a mounting defect in which the component E is missing, conditions for retrieving a posture image of the corresponding component E from the side immediately before mounting and/or an image of the nozzle on which the corresponding component E has been mounted from the side immediately after mounting are set as the second search condition. In the case of a mounting defect of Manhattan in which the component E rises up, conditions for retrieving a print inspection image of the corresponding mounting position, a component recognition image of the corresponding component E from below, and/or a mark recognition image of the corresponding board S (fiducial marks of the entire board or a local fiducial mark of the board) are set as the second search condition. In the case of a mounting defect in which the component E is mismounted, a condition for retrieving a component recognition image of the corresponding component E from below is set as the second search condition.

The CPU 21 performs a control to store OK/NG of the inspection result of component mounting in the storage 22, and display images of the same type of another component E with an NG inspection result as the related images 32 together with the selected image 31 when the selected image 31 is an image with an NG inspection result. The inspection result is NG when the component E is not correctly mounted on the board S. The inspection result is OK when the component E is correctly mounted on the board S.

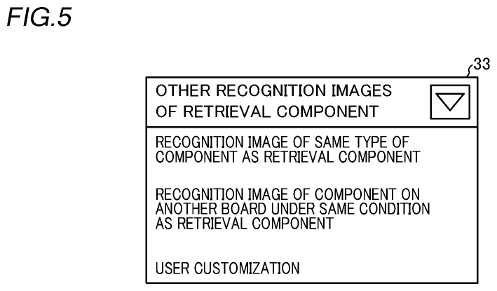

As shown in FIG. 4, the CPU 21 performs a control to display the second search condition together with the related images 32. As shown in FIG. 5, the second search condition is selectable by a pull-down display 33. That is, when a plurality of second search conditions can be set for the selected image 31, the CPU 21 retrieves the related images 32 according to one second search condition selected based on a user's selection or a predetermined condition among a plurality of settable second search conditions. Furthermore, the CPU 21 performs a control to display a plurality of second search conditions in a selectable manner together with the selected image 31.

The second search condition for retrieving the related images 32 is a condition for retrieving another recognition image of the component E in the selected image 31, a recognition image of the same type of component E as the component E in the selected image 31, and a recognition image of the component E on another board S under the same condition as the component E in the selected image 31, for example. Furthermore, the second search condition can be customized by the user.

The plurality of second search conditions may be automatically switched at regular time intervals. In this case, the search conditions having a large number of times of display are stored in the storage 22 and preferentially displayed. The conditions are scored for elements (a component E, a board S, a tool, and component supply) in the search conditions, and the display order is set so as to give priority to the display of the condition having a high score.

According to this embodiment, the following advantageous effects are achieved.

According to this embodiment, as described above, the CPU 21 is configured to perform a control to retrieve images from the plurality of images in the DB 25 according to the first search condition set by the user, and display the related images 32 retrieved according to the second search condition different from the first search condition based on the information on the selected image 31 together with the selected image 31 selected by the user from the retrieved images. Accordingly, the CPU 21 retrieves the related images 32 according to the second search condition different from the first search condition used to retrieve the selected image 31 based on the information on the selected image 31, and thus the related images 32 can be extracted without associating a plurality of images in advance. Consequently, it is not necessary for the user to perform a separate retrieval, and thus it is possible to easily confirm a plurality of related images captured during the mounting operation that have not been associated in advance. Furthermore, the selected image 31 and the related images 32 are displayed on the same screen, and thus it is possible to easily understand the mounting state and identify the cause of the defect.

According to this embodiment, as described above, the first search condition is a condition set based on the information including at least one of the component information, the board information, the information on a component mounting position, the information on a working device that works on a board, the information on a working unit that works on a board, the information on a component supply unit that supplies components, or the information on a work date and time. Accordingly, images can be retrieved according to the first search condition set by the user based on the component information, the board information, the information on a component mounting position, the information on a working device that works on a board, the information on a working unit that works on a board, the information on a component supply unit that supplies components, or the information on a work date and time.

According to this embodiment, as described above, the CPU 21 is configured to perform a control to display the plurality of related images 32 together with the selected image 31. Accordingly, the plurality of related images 32 can be confirmed together with the selected image 31, and thus it is possible to more easily understand the mounting state and identify the cause of the defect.

According to this embodiment, as described above, the CPU 21 is configured to store the information on the related image 32 selected from the plurality of related images 32 with respect to the selected image 31 in the storage 22, and reflect the information on the related image 32 stored in the storage 22 to set the second search condition. Accordingly, the second search condition can be set such that the related images 32 frequently selected among the plurality of related images 32 are easily retrieved, and thus more suitable related images 32 can be extracted.

According to this embodiment, as described above, the CPU 21 is configured to retrieve the related images 32 according to the second search condition according to the type of mounting defect when the selected image 31 selected by the user is an image related to the mounting defect of the component E. Accordingly, the related images 32 for identifying the cause can be displayed according to the type of mounting defect, and thus the user can efficiently confirm the images. Thus, the user can efficiently perform an operation to identify the mounting defect. Furthermore, it is possible to prevent extraction of images having low relevance according to the type of mounting defect, and thus the retrieval operation can be performed efficiently while the retrieval time can be shortened.

According to this embodiment, as described above, the CPU 21 is configured to perform a control to store OK/NG of the inspection result of component mounting in the storage 22, and display images of the same type of another component E with an NG inspection result as the related images 32 together with the selected image 31 when the selected image 31 is an image with an NG inspection result. Accordingly, it is not necessary for the user to retrieve and display another similar image with an NG inspection result, and thus the work burden can be reduced. Furthermore, similar images with an NG inspection result can be displayed in a list, and thus it is possible to more easily understand the mounting state and identify the cause of the defect.

According to this embodiment, as described above, the CPU 21 is configured to perform a control to display the second search condition together with the related images 32. Accordingly, the user can visually confirm the search condition of the related images 32 displayed together with the selected image 31.

According to this embodiment, as described above, the CPU 21 is configured to retrieve the related images 32 according to one second search condition selected based on the user's selection or the predetermined condition among the plurality of settable second search conditions when the plurality of second search conditions are settable for the selected image 31. Accordingly, the related images 32 can be retrieved according to one second search condition selected from the plurality of second search conditions, and thus the related images 32 can be retrieved according to a more suitable search condition.

According to this embodiment, as described above, the CPU 21 is configured to perform a control to display a plurality of second search conditions in a selectable manner together with the selected image 31. Accordingly, the user can easily select a desired search condition from the plurality of second search conditions.

### MODIFIED EXAMPLES

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the image search device is provided as a device configured to control the process of the component mounting line has been shown in the aforementioned embodiment, the present disclosure is not restricted to this. In the present disclosure, the image search device may be provided separately from a control device configured to control the process of the component mounting line.

While the example in which components are supplied from the tape feeders to the component mounting devices has been shown in the aforementioned embodiment, the present disclosure is not restricted to this. In the present disclosure, components may be supplied from trays to the component mounting devices.

While the example in which the board is conveyed along one lane and the mounting operation is performed thereon has been shown in the aforementioned embodiment, the present disclosure is not restricted to this. In the present disclosure, the boards may be conveyed along two or more lanes, and the mounting operation may be performed thereon.

While the example in which a so-called in-line head unit including a plurality of mounting heads linearly provided in one row or a plurality of rows is provided has been shown in the aforementioned embodiment, the present disclosure is not restricted to this. In the present disclosure, a so-called rotary head unit including a plurality of mounting heads circumferentially provided may be provided.

While the example in which one head unit is provided has been shown in the aforementioned embodiment, the present disclosure is not restricted to this. In the present disclosure, a plurality of head units may be provided.

While the example in which the three component mounting devices are provided in one component mounting line has been shown in the aforementioned embodiment, the present disclosure is not restricted to this. In the present disclosure, two or less or four or more component mounting devices may be provided in one component mounting line.

What is claimed is:

1. An image search device comprising:
an image storage configured to store a plurality of images captured in a mounting process to mount a component on a board; and
a controller configured to retrieve an image according to a search condition from the plurality of images stored in the image storage; wherein
the controller is configured to perform a control to retrieve an image from the plurality of images in the image storage according to a first search condition set by a user, and display, together with a selected image selected by the user from the retrieved image, a related image retrieved according to a second search condition different from the first search condition based on information on the selected image.

2. The image search device according to claim 1, wherein the first search condition is a condition set based on information including at least one of component information, board information, information on a component mounting position, information on a working device that works on the board, information on a working unit that works on the board, information on a component supply unit that supplies the component, or information on a work date and time.

3. The image search device according to claim 1, wherein the controller is configured to perform a control to display a plurality of the related images together with the selected image.

4. The image search device according to claim 3, wherein the controller is configured to store information on the related image selected from the plurality of related images with respect to the selected image in a storage, and reflect the information on the related image stored in the storage to set the second search condition.

5. The image search device according to claim 1, wherein the controller is configured to retrieve the related image according to the second search condition according to a type of mounting defect when the selected image selected by the user is an image related to a mounting defect of the component.

6. The image search device according to claim 1, wherein the controller is configured to perform a control to store OK/NG of an inspection result of component mounting in a storage, and display an image of a same type of another component with an NG inspection result as the related image together with the selected image when the selected image is an image with an NG inspection result.

7. The image search device according to claim 1, wherein the controller is configured to perform a control to display the second search condition together with the related image.

8. The image search device according to claim 1, wherein the controller is configured to, when a plurality of the second search conditions are settable for the selected image, retrieve the related image according to one second search condition selected based on a user's selection or a predetermined condition among the plurality of settable second search conditions.

9. The image search device according to claim 8, wherein the controller is configured to perform a control to display the plurality of second search conditions in a selectable manner together with the selected image.

10. A component mounting system comprising:
a component mounting device configured to mount a component on a board; and
an image search device; wherein
the image search device includes:
an image storage configured to store a plurality of images captured in a mounting process to mount the component on the board; and
a controller configured to retrieve an image according to a search condition from the plurality of images stored in the image storage; and
the controller is configured to perform a control to retrieve an image from the plurality of images in the image storage according to a first search condition set by a user, and display, together with a selected image selected by the user from the retrieved image, a related image retrieved according to a second search condition different from the first search condition based on information on the selected image.

11. An image search method comprising:
storing a plurality of images captured in a mounting process to mount a component on a board; and
retrieving an image from the plurality of stored images according to a first search condition and displaying, together with a selected image selected from the retrieved image, a related image retrieved according to a second search condition different from the first search condition based on information on the selected image.

12. The image search method according to claim 11, wherein the first search condition is a condition set based on information including at least one of component information, board information, information on a component mounting position, information on a working device that works on the board, information on a working unit that works on the board, information on a component supply unit that supplies the component, or information on a work date and time.

13. The image search method according to claim 11, wherein a plurality of the related images are displayed together with the selected image.

14. The image search method according to claim 11, wherein the related image is retrieved according to the second search condition according to a type of mounting defect when the selected image is an image related to a mounting defect of the component.

15. The image search method according to claim 11, wherein, wherein OK/NG of an inspection result of component mounting is stored, and an image of a same type of another component with an NG inspection result is displayed as the related image together with the selected image when the selected image is an image with an NG inspection result.

16. The image search method according to claim 11, wherein the second search condition is displayed together with the related image.

17. The image search device according to claim 2, wherein the controller is configured to perform a control to display a plurality of the related images together with the selected image.

18. The image search device according to claim 2, wherein the controller is configured to retrieve the related image according to the second search condition according to a type of mounting defect when the selected image selected by the user is an image related to a mounting defect of the component.

19. The image search device according to claim 2, wherein the controller is configured to perform a control to store OK/NG of an inspection result of component mounting in a storage, and display an image of a same type of another component with an NG inspection result as the related image together with the selected image when the selected image is an image with an NG inspection result.

20. The image search device according to claim 2, wherein the controller is configured to perform a control to display the second search condition together with the related image.
